(19) United States
(12) Patent Application Publication
(10) Pub. No.: US 2020/0350126 A1
(43) Pub. Date: Nov. 5, 2020

(54) ELECTROPHOTOGRAPHIC ACTIVE INK COMPOSITIONS

(71) Applicant: Hewlett-Packard Development Company, L.P., Spring, TX (US)

(72) Inventors: Getahun Biadglin, Nes Ziona (IL); Yaron Grinwald, Nes Ziona (IL); Emad Masoud, Nes Ziona (IL); Shahar Stein, Nes Ziona (IL); Ofir Bros, Nes Ziona (IL)

(21) Appl. No.: 16/771,526

(22) PCT Filed: Jan. 18, 2018
(86) PCT No.: PCT/US2018/014250

§ 371 Date: Jun. 10, 2020

(51) Int. Cl. H01G 9/20; G03G 9/13; G03G 9/135; G03G 9/12; H01G 9/00; H01L 51/00; H01L 51/42; H01L 51/44

(52) U.S. Cl. CPC H01G 9/2059; G03G 9/131; G03G 9/1355; G03G 9/122; H01L 51/442; H01L 51/0005; H01L 51/0022; H01L 51/4253; H01G 9/0029

(57) ABSTRACT

The present disclosure relates to an electrophotographic active ink composition comprising a thermoplastic polymer comprising a copolymer of an olefin and acrylic acid and/or metacrylic acid; active photovoltaic material comprising electron donor material and electron acceptor material; a charge adjuvant, and a liquid carrier.

### BACKGROUND

A photovoltaic cell converts light energy into electrical energy. A photovoltaic cell may comprise one or more active layers positioned between an anode and a cathode. When light falls on the active layer, the light is absorbed and generates particles with a positive or negative charge (holes and electrons). When an external load is connected between electrodes, electricity flows through the cell.

### DETAILED DESCRIPTION

Before the present disclosure is disclosed and described, it is to be understood that this disclosure is not limited to the particular process steps and materials disclosed in this disclosure because such process steps and materials may vary. It is also to be understood that the terminology used in this disclosure is used for the purpose of describing particular examples. The terms are not intended to be limiting because the scope is intended to be limited by the appended claims and equivalents thereof.

It is noted that, as used in this specification and the appended claims, the singular forms “a,” “an,” and “the” include plural referents unless the context clearly dictates otherwise.

As used in this disclosure, “carrier fluid”, “carrier liquid,” “carrier,” or “carrier vehicle” refers to the fluid in which polymers, particles, charge directors and other additives can be dispersed to form a liquid electrostatic composition or liquid electrophotographic composition. The carrier liquids may include a mixture of a variety of different agents, such as surfactants, co-solvents, viscosity modifiers, and/or other possible ingredients.

As used in this disclosure, “electrophotographic composition” or “electrostatic composition” generally refers to a composition, which is suitable for use in an electrophotographic or electrostatic printing process. The electrophotographic composition may comprise chargeable particles of polymer dispersed in a carrier liquid.

As used in this disclosure, “co-polymer” refers to a polymer that is polymerized from at least two monomers. The term “terpolymer” refers to a polymer that is polymerized from 3 monomers.

As used in this disclosure, “melt index” and “melt flow rate” are used interchangeably. The “melt index” or “melt flow rate” refers to the extrusion rate of a resin through an orifice of defined dimensions at a specified temperature and load, reported as temperature/load, e.g. 190° C./2.16 kg. In the present disclosure, “melt flow rate” or “melt index” is measured per ASTM D1238-04c Standard Test Method for Melt Flow Rates of Thermoplastics by Extrusion Plastometer. If a melt flow rate of a particular polymer is specified, unless otherwise stated, it is the melt flow rate for that polymer alone, in the absence of any of the other components of the electrostatic composition.

As used in this disclosure, “acidity,” “acid number,” or “acid value” refers to the mass of potassium hydroxide (KOH) in milligrams that neutralizes one gram of a substance. The acidity of a polymer can be measured according to standard techniques, for example as described in ASTM D1386. If the acidity of a particular polymer is specified, unless otherwise stated, it is the acidity for that polymer alone, in the absence of any of the other components of the liquid toner composition.

As used in this disclosure, “melt viscosity” generally refers to the ratio of shear stress to shear rate at a given shear stress or shear rate. Testing may be performed using a capillary rheometer. A plastic charge is heated in the rheometer barrel and is forced through a die with a plunger. The plunger is pushed either by a constant force or at constant rate depending on the equipment. Measurements are taken once the system has reached steady-state operation. One method used is measuring Brookfield viscosity @140° C., units are mPa-s or cPoise, as known in the art. Alternatively, the melt viscosity can be measured using a rheometer, e.g. a commercially available AR-2000 Rheometer from Thermal Analysis Instruments, using the geometry of: 25 mm steel plate-standard steel parallel plate, and finding the plate over plate rheometry isotherm at 120° C., 0.01 Hz shear rate. If the melt viscosity of a particular polymer is specified, unless otherwise stated, it is the melt viscosity for that polymer alone, in the absence of any of the other components of the electrostatic composition.

A polymer may be described as comprising a certain weight percentage of monomer. This weight percentage is indicative of the repeating units formed from that monomer in the polymer.

If a standard test is mentioned in this disclosure, unless otherwise stated, the version of the test to be referred to is the most recent at the time of filing this patent application.

As used in this disclosure, “electrostatic printing” or “electrophotographic printing” refers to the process that provides an image that is transferred from a photo imaging plate either directly or indirectly via an intermediate transfer member to a print substrate. As such, the image may not be substantially absorbed into the photo imaging substrate on which it is applied. Additionally, “electrophotographic printers” or “electrostatic printers” refer to those printers capable of performing electrophotographic printing or electrostatic printing, as described above. An electrophotographic printing process may involve subjecting the electrophotographic composition to an electric field, e.g. an electric field having a field gradient of 1-400V/μm, or more, in some examples 600-900V/μm, or more.

As used in this disclosure, “substituted” may indicate that a hydrogen atom of a compound or moiety is replaced by another atom such as a carbon atom or a heteroatom, which is part of a group referred to as a substituent. Substituents include, for example, alkyl, alkoxy, aryl, aryloxy, alkenyl, alkenoxy, alkynyl, alkynoxy, thioalkyl, thioalkenyl, thioalkynyl, thioaryl, etc.

As used in this disclosure, “heteroatom” may refer to nitrogen, oxygen, halogens, phosphorus, or sulfur.

As used in this disclosure, “alkyl”, or similar expressions such as “alk” in alkaryl, may refer to a branched, unbranched, or cyclic saturated hydrocarbon group, which may, in some examples, contain from 1 to about 50 carbon atoms, or 1 to about 40 carbon atoms, or 1 to about 30 carbon atoms, or 1 to about 10 carbon atoms, or 1 to about 5 carbon atoms, for example.

The term “aryl” may refer to a group containing a single aromatic ring or multiple aromatic rings that are fused together, directly linked, or indirectly linked (such that the different aromatic rings are bound to a common group such as a methylene or ethylene moiety). Aryl groups described in this disclosure may contain, but are not limited to, from 5 to about 50 carbon atoms, or 5 to about 40 carbon atoms, or 5 to 30 carbon atoms or more, and may be selected from, phenyl and naphthyl.

Unless the context dictates otherwise, the terms “acrylic” and “acrylate” refer to any acrylic or acrylate compound. For example, the term “acrylic” includes acrylic and methacrylic compounds unless the context dictates otherwise. Similarly, the term “acrylate” includes acrylate and methacrylate compounds unless the context dictates otherwise.

As used in this disclosure, the term “about” is used to provide flexibility to a numerical range endpoint by providing that a given value may be a little above or a little below the endpoint to allow for variation in test methods or apparatus. The degree of flexibility of this term can be dictated by the particular variable and would be within the knowledge of those skilled in the art to determine based on experience and the associated description in this disclosure.

As used in this disclosure, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented in this disclosure in a range format. It is to be understood that such a range format is used merely for convenience and brevity and thus should be interpreted flexibly to include not just the numerical values explicitly recited as the limits of the range, but also to include all the individual numerical values or sub-ranges encompassed within that range as if each numerical value and sub-range is explicitly recited. As an illustration, a numerical range of “about 1 wt % to about 5 wt %” should be interpreted to include not just the explicitly recited values of about 1 wt % to about 5 wt %, but also include individual values and subranges within the indicated range. Thus, included in this numerical range are individual values such as 2, 3.5, and 4 and sub-ranges such as from 1-3, from 2-4, and from 3-5, etc. This same principle applies to ranges reciting a single numerical value. Furthermore, such an interpretation should apply regardless of the breadth of the range or the characteristics being described.

As used in this disclosure, weight % (wt %) values are to be taken as referring to a weight-for-weight (w/w) percentage of solids in the composition, and not including the weight of any carrier fluid present.

In one aspect, there is provided an electrophotographic active ink composition comprising a thermoplastic polymer comprising a copolymer of an olefin and acrylic acid and/or methacrylic acid; active photovoltaic material comprising electron donor material and electron acceptor material; a charge adjuvant, and a liquid carrier.

In another aspect, there is provided a method of assembling a photovoltaic cell. The method comprises electrophotographically printing an active photovoltaic layer over a transparent anode using an electrophotographic active ink composition. The electrophotographic active ink composition comprises a thermoplastic polymer comprising a copolymer of an olefin and acrylic acid and/or methacrylic acid; active photovoltaic material comprising electron donor material and electron acceptor material; a charge adjuvant, and liquid carrier. A cathode is then electrophotographically printed over the active photovoltaic layer using an electrophotographic electrode ink composition comprising a thermoplastic polymer comprising a copolymer of an olefin and acrylic acid and/or methacrylic acid; an electrically conductive material comprising carbon or metal; a charge adjuvant, and a liquid carrier.

In yet another aspect, there is provided an electrophotographicaly printed photovoltaic cell comprising a transparent anode, an electrophotographically printed active photovoltaic layer overlying the transparent anode, and an electrophotographically printed cathode overlying the electrophotographically printed active photovoltaic layer, wherein the electrophotographically printed active photovoltaic layer comprises a thermoplastic resin comprising a copolymer of an olefin and acrylic acid and/or methacrylic acid, and a mixture of electron donor material and electron acceptor material.

In the present disclosure, it has been found that an active photovoltaic layer may be printed by electrophotographic printing. In particular, an electrophotographic active ink composition has been developed that allows an active photovoltaic layer to be electrophotographically printed. In some examples, the printed layer may provide a bulk heterojunction active photovoltaic layer, which comprises an admixture of electron donor material and electron acceptor material. In some examples, the bulk heterojunction active photovoltaic layer may provide a percolating network of electron-donating and electron-accepting domains that can facilitate the transport of charge from the electron donor material to the hole-transporting electrode (anode), and the transport of charge from the acceptor materials to the electron-transporting electrode (cathode). This transport of charge allows electricity to be generated by the photovoltaic cell, when the cell is irradiated by light. It has surprisingly been found that, by tailoring the electrophotographic active ink composition and/or the electrophotographic printing conditions, it is possible to control the morphology of bulk heterojunction to facilitate and/or improve photovoltaic performance.

### Electrophotographic Active Ink Composition

As described above, the electrophotographic active ink composition comprises a thermoplastic polymer comprising a copolymer of an olefin and acrylic acid and/or methacrylic acid; active photovoltaic material comprising electron donor material and electron acceptor material; a charge adjuvant, and a liquid carrier. In some examples, the electrophotographic active ink composition may also include a charge director.

Suitable thermoplastic polymers are described in further detail below. However, in some examples the thermoplastic polymer may comprise a copolymer of an olefin (e.g. ethylene) and acrylic acid. The copolymer may comprise 10 to 30 weight % of units derived from acrylic acid, for example, 12 to 25 weight % of 15 to 20 weight %.

The thermoplastic polymer may be present in the electrophotographic active ink composition in an amount of 10 to 90 weight % based on the total weight of solids in the composition. In some examples, the thermoplastic polymer may be present in an amount of 15 to 80 weight %, for instance, 20 to 70 weight % or of the total weight of solids in the composition. In some examples, thermoplastic polymer may be present in an amount of 25 to 60 weight % or 30 to 55 weight % based on the total weight of solids in the composition.

The active photovoltaic material may be present in the electrophotographic active ink composition in an amount of 5 to 90 weight %, for example, 10 to 80 weight % or 15 to 75 weight % based on the total weight of solids in the composition. In some examples, the total weight of active photovoltaic material in the composition is 20 to 70 weight %, for example, 30 to 68 weight % based on the total weight of solids of the composition.

The active photovoltaic material comprises electron donor material and electron acceptor material. In some examples, the active photovoltaic material consists essentially of electron donor material and electron acceptor material. Any suitable electron donor material may be used. Any suitable electron acceptor material may be used.

Suitable electron donor materials include conjugated organic materials. Conjugated organic materials may include delocalised a electrons that result from carbon p orbital hybridisation. These a electrons can be excited by light from the molecule's highest occupied molecular orbital (HOMO) to the lowest unoccupied molecular orbital (LUMO), denoted by a π-π* transition. The energy bandgap between these orbitals determines which wavelengths of light that can be absorbed. The conjugated organic material may be selected from phthaiocyanines and polythiophenes. Other examples include poly(phenylene vinylenes) (PPV's), polyfluorenes, poly(p-phenylene) and quinolines. For the avoidance of doubt, the term “phthalocyanine” includes phthalocyanine and phthalocyanine derivatives. Similarly, the term “poythiophene” includes poythiophene and polythiophene derivatives; the term “poly(phenylene vinylenes)” includes poly(phenylene vinylene) and its derivatives; the term “poyfluorenes” includes poyfluorene and its derivatives, the term “poly(p-phenylene)” includes poly(p-phenylene) and its derivatives; and the term “quinoline” includes quinoline and its derivatives.

Examples of suitable phthaocyanines include metal phthalocyanine, for instance, zinc phthalocyanine, magnesium phthalocyanine, cobalt phthalocyanine, nickel phthalocyanine and/or copper phthalocyanine. Examples of suitable poythiophenes include poly(alkylthiophenes). The alkyl group may be a C₁ to C₁₂ alkyl group, for example, a C₆ to C₈ alkyl group. In some examples, the poythiophene may be a poly(3-hexylthiophene-2,5-diyl) or a poly(3-octylthiophene-2,5-diyl).

Other examples of suitable electron donor materials include small molecules, for example:

Benz[b]anthracene; 2,4-bis[4-(N,N-dibenzylamino-2,6-dihydroxyphenyl]squaraine; 5,5″″-Bis(2″″′,2″″′-dicyanovinyl)-2,2′:5′,2″:5″,2″′:5″′,2″″-quinquethiophene; 2,4-Bis[4-(N,N-diisobutylamino)-2,6-dihydroxyphenyl]squaraine; 2,4-Bis[4-(N,N-diphenylamino)-2,6-dihydroxyphenyl]squaraine; 2-[(7-{4-[N,N-Bis(4-methylphenyl)amino]phenyl}-2,1,3-benzothiadiazol-4-yl)methylene]propanedinitrile; is-Bis(isothiocyanato)(2,2′-bipyrdyl-4,4′-dicarboxylato)(4,4′-bis(5-hexylthiophen-2-yl)-2,2′-bipyridyl)ruthenium(II) (C101 dye); cis-Bis(isothiocyanato)(2,2′-bipyridyl-4,4′-dicarboxylato)(4,4′-bis(5-(hexylthio)thiophen-2-yl)-2,2′-bipyridyl)ruthenium(II) (C106 dye); D102 dye; 2-Cyano-3-[4-[4-(2,2-diphenylethenyl)phenyl]-1,2,3,3a,4,8b-hexahydrocyclopent[b]indol-7-yl]-2-propenoic acid (D131 dye); 5-[3-(Carboxymethyl)-5-[[4-[4-(2,2-diphenylethenyl)phenyl]-1,2,3,3a,4,8b-hexahydrocyclopent[b]indol-7-yl]methylene]-4-oxo-2-thiazoli dinylidene]-4-oxo-2-thioxo-3-thiazolidinedodecanoic acid (D358 dye); 5,10,15,20-Tetraphenylbisbenz[5,6]indeno[1,2,3-cd:1′,2′,3′-Im]perylene (DBP); 5,5″″′-Dihexyl-2,2:5′,2″:5″,2″:5″′,2″′:5″′,2″″′-sexithiophene; 2-[7-(4-Diphenylaminophenyl-2,1,3-benzothiadiazol-4-yl]methylenepropanedinitrle; 2-{[7-(5-N,N-Ditolylaminothiophen-2-yl)-2,1,3-benzothiadiazol-4-yl]methylene}malononitrile; 7,7′-[4,4-Bis(2-ethylhexyl)-4H-silolo[3,2-b:4,5-b′]dithiophene-2,6-diyl]bis[6-fluoro-4-(5′-hexyl-[2,2′-bithiophen]-5-yl)benzo[c][1,2,5]thiadiazole] (DTS(FBTTh₂)₂); 4,4′-[4,4-Bis(2-ethylhexyl)-4H-silolo[3,2-b:4,5-b′dithophene-2,6-diyl]bis[7-(5′-hexyl-[2,2′-bthiophen]-5-yl)-[1,2,5]thiadiazolo[3,4-c]pyridine] (DTS(PTTh₂)₂); Ru(4,4-dicarboxylic acid-2,2′-bipyridine)(4,4′-bis(p-hexyloxystyryl)-2,2-bipyridine)(NCS)₂ (K19 Dye); Merocyanine dye (HB194); Tris(N,N,N-tributyl-1-butanaminium)[[2,2″6′,2″-terpyrdine]-4,4′,4″-tricarboxylato(3-)-N1,N1′,N1″]tris(thiocyanato-N)hydrogen ruthenate(4-) (N749 Black Dye); pentacene; alpha-sexithiophene; 2,5-Di-(2-ethylhexyl)-3,6-bis-(5″-n-hexyl-[2,2,5′,2″]terthiophen-5-yl)-pyrrolo[3,4-c]pyrrole-1,4-dione (SMDPPEH); 2,5-Dioctyl-3,6-bis-(5″-n-hexyl-[2,2′,5′,2″ ]terthiophen-5-yl)-pyrrolo[3,4-c]pyrrole-1,4-dione (SMDPPO); Tin(IV) 2,3-naphthalocyanine dichloride; and tris[4-(5-dicyanomethylidenemethyl-2-thienyl)phenyl]amine. Mixtures of two or more of the above small molecules may be employed.

Other examples of electron donor materials include conjugated organic polymers, for instance:

Poly[2-methoxy-5-(3′,7′-dimethyloctyloxy)-1,4-phenylenevinylene (MDMO-PPV); Poly[2-methoxy-5-(2-ethylhexyloxy)-1,4-phenylenevinylene] (MEH-PPV, Mn 40,000-70,000 or 70,000-100,000 or 150,000-250,000); Poly[(5,6-dihydro-5-octyl-4,6-dioxo-4H-thieno[3,4-C]pyrrole-1,3-diyl){4,8-bis[(2-butyloctyl)oxy]benzo[1,2-b:4,5-b′]dithiophene-2,6-diyl}] (PBDTBO-TPDO); Poly[(5,6-dihydro-5-octyl-4,6-dioxo-4H-thieno[3,4-c]pyrrole-1,3-diyl)[4,8-bis[(2-ethylhexyl)oxy]benzo[1,2-b:4,5-b′]dithiophene-2,6-diyl]] (PBDT(EH)-TPD(Oct); Poly[[5-(2-ethylhexyl)-5,6-dihydro-4,6-dioxo-4H-thieno[3,4-c]pyrrole-1,3-diyl][4,8-bis[(2-ethylhexyl)oxy]benzo[1,2-b:4,5-b′]dithiophene-2,6-diyl]] (PBDT-TPD, average Mn 10,000-50,000, PDI≤3.0); Poly[1-(6-{4,8-bis[(2-ethylhexyl)oxy]-8-methylbenzo[1,2-b:4,5-b′]dithiophen-2-yl}-3-fluoro-4-methylthieno[3,4-b]thiophen-2-yl)-1-octanone] (PBDTTT-CF); Poly[[5-(2-ethylhexyl)-5,6-dihydro-4,6-dioxo-4H-thieno[3,4-c]pyrrole-1,3-diyl](4,4′-didodecyl[2,2′-bithiophene]-5,5′-diyl] (PBTTPD); Poly[N-9′-heptadecanyl-2,7-carbazole-alt-5,5-(4′,7′-di-2-thienyl-2′,1′,3′-benzothiadiazole)] (PCDTBT); Poly[2,6-(4,4-bis-(2-ethylhexyl)-4H-cyclopenta [2,1-b;3,4-b′]dithiophene)-alt-4,7(2,1,3-benzothiadiazole)] (PCPDTBT, average Mw 7000-20000); Poly[(5,6-dihydro-5-octyl-4,6-dioxo-4H-thieno[3,4-c]pyrrole-1,3-diyl)[4,4-bis(2-ethylhexyl)-4H-silolo[3,2-b:4,5-b′;]dithiophene-2,6-diyl]] (PDTSTPD); Poly[(5,6-difluoro-2,1,3-benzothiadiazol-4,7-diyl)-alt-(3,3″′-di(2-octyldodecyl)-2,2′,5′,2″,5″,2″′-quaterthiophen-5,5″′-diyl)] (PffBT4T-2OD); Poly[2,7-(9,9-dioctylfluorene)-alt-4,7-bis(thiophen-2-ylbenzo-2,1,3-thiadiazole] (PFODBT, average Mw 10,000-50,000); Poly([2,6′-4,8-di(5-ethylhexythienyl)benzo[1,2-b;3,3-b]dithiophene]{3-fluoro-2[(2-ethylhexyl)carbonyl]thieno[3,4-b]thiophenediyl}); Poly(3-dodecylthiophene-2,5-diyl) electronic grade, 99.995% trace metals basis, average Mw˜27,000; Poly(3-octylthiophene-2,5-diyl) (regioregular, average Mn ˜25,000); Poly[2,7-(9,9-dioctyl-dibenzosilole)-alt-4,7-bis(thiophen-2-yl)benzo-2,1,3-thiadiazole] (PSiF-DBT Mw 10,000-80,000); Poly({4,8-bis[(2-ethylhexyl)oxy]benzo[1,2-b:4,5-b′]dithiophene-2,6-diyl}(3-fluoro-2-[(2-ethylhexyl)carbonyl]thieno[3,4-b]thiophenediyl}) (PTB7 average Mw 80,000-200,000, PDI≤3.0); and Poly[[2,3-bis(3-octyloxyphenyl)-5,8-quinoxalinediyl]-2,5-thiophenediyl] (TQ1). Mixtures of two or more of these polymers may be employed.

The electron acceptor material may be a fullerene or a perylene compound. For the avoidance of doubt, the term “fullerene” is used herein to denote unfunctionalized and functionalised fullerenes, fullerene compounds and derivatives. Examples of suitable fullerenes include C₆₀ or C₇₀, or compounds or derivatives of C₆₀ or C₇₀. Specific examples include:

4-(1′,5′-Dihydro-1′-methyl-2′H-[5,6]fullereno-C₆₀-Iₕ-[1,9-c]pyrrol-2′-yl)benzoic acid; Bis(1-[3-(methoxycarbonyl)propyl]-1-phenyl)-[6.6]C₆₂ (mixture of isomers); [5,6]-Fullerene-C70; Fullerene-C60; Fullerene-C₈₄; 1′,1″,4′,4″-Tetrahydro-di[1,4]methanonaphthaleno[1,2:2′,3′,56,60:2″,3″][5,6]fullerene-C₆₀ (ICBA); 1′,4′-Dihydro-naphtho[2,3′:1,2][5,6]fullerene-C₆₀ (ICMA); [6,6]-Pentadeuterophenyl C61 butyric acid methyl ester; Perylene-3,4,9,10-tetracarboxylic dianhydride; [6,6]-Phenyl-C61 butyric acid butyl ester; [6,6]-Phenyl C61 butyric acid methyl ester; [6,6]-Phenyl C71 butyric acid methyl ester, mixture of isomers; [6,6]-Phenyl-C61 butyric acid octyl ester; 5,5′-(2,1,3-Benzothiadiazole-4,7-diyldi-2,1-ethenediyl)bis[2-hexyl-1H-isoindole-1,3(2H)-dione] (PIBT); Poly(benzimidazobenzoohenanthroline): Polyhydroxy small gap fullerenes, hydrated; small gap fullerene-ethyl nipecotate; small gap fullerenes; and [6,6]-Thienyl C₆₁ butyric acid methyl ester≥99%. Mixtures of such compounds may be employed.

Quinacridones and their derivatives may also be employed as electron acceptor materials.

The electrophotographic active ink composition may include 8 to 85 weight % of the electron donor material based on the total weight of solids in the composition. In some examples, the electrophotographic active ink composition may include 8 to 40 weight %, for instance, 10 to 43 weight % or 15 to 25 weight % of the electron donor material based on the total weight of solids in the composition.

The electrophotographic active ink composition may include 8 to 85 weight % of the electron acceptor material based on the total weight of solids in the composition. In some examples, the electrophotographic active ink composition may include 8 to 40 weight %, for instance, 10 to 43 weight % or 15 to 25 weight of the electron acceptor material based on the total weight of solids in the composition.

The weight ratio of electron donor material to electron acceptor material may be 1:2 to 2:1, for example, 1:1.5 to 1.5:1. In some examples, the ratio may be about 1:1.

The ratio of the total weight of active photovoltaic material to the total weight of thermoplastic polymer is 1:5 to 1:1, for example 1:4 to 1:1.5 or 1:3 to 1:2.

The electrophotographic active ink composition may include 8 to 85 weight % of the active photovoltaic material (e.g. total amount of electron donor material and total amount of electron acceptor material) based on the total weight of solids in the composition. In some examples, the electrophotographic active ink composition may include 10 to 80 weight %, for instance, 20 to 75 weight % or 30 to 70 weight % of the electron acceptor material based on the total weight of solids in the composition.

As mentioned above, the electrophotographic active ink composition includes a charge adjuvant and a liquid carrier. A charge director may also be present. These components are described in further detail below.

### Electrophotographic Electrode Ink Composition

In some examples, the electrophotographic active ink composition may form part of a material set. The material set may additionally include an electrophotographic electrode ink composition. The electrophotographic electrode ink composition may comprise a thermoplastic polymer comprising a copolymer of an olefin and acrylic acid and/or methacrylic acid; an electrically conductive material comprising carbon or metal; a charge adjuvant, and a liquid carrier. The electrophotographic electrode ink composition may be used to produce the cathode of the cell as will be described further below.

Suitable thermoplastic polymers for the electrophotographic electrode ink composition are described in further detail below. The thermoplastic polymer employed may be the same or different from the thermoplastic polymer employed in the electrophotographic active ink composition. In some examples the thermoplastic polymer may comprise a copolymer of an olefin (e.g. ethylene) and acrylic acid. The copolymer may comprise 10 to 30 weight % of units derived from acrylic acid, for example, 12 to 25 weight % of 15 to 20 weight %.

The thermoplastic polymer may be present in the liquid electrophotographic electrode ink composition in an amount of 10 to 90 weight % based on the total weight of solids in the composition. In some examples, the thermoplastic polymer may be present in an amount of 15 to 80 weight %, for instance, 20 to 70 weight % or of the total weight of solids in the composition. In some examples, thermoplastic polymer may be present in an amount of 25 to 60 weight % or 30 to 55 weight % based on the total weight of solids in the composition.

The electrically conductive material may be an electroconductive carbon material. For instance, graphite, carbon black, graphene and/or carbon nanotubes (CNT) may be used. The electrically conductive material (e.g. carbon material) may be present in an amount of 1 to up to 100 weight %, for example, 1 to 99 weight % or 1 to 97 weight % of the total weight of solids in the composition. Where the electrically conductive material comprises a carbon material (e.g. CNT), the material may be present in an amount of 1 to 70 weight %, for example, 10 to 65 weight % or 30 to 60 weight % or 35 to 55 weight % of the total weight of solids in the composition. Where the electrically conductive material comprises a metal, the metal may be present in an amount of 50 to up to 100 weight % of the total weight of solids in the composition, for instance, 70 to 97 weight % of the total weight of solids in the composition.

Alternatively, the electrically conductive material may be a metal, for example, metal particles or metal powder. Examples include aluminium, calcium, gold, palladium, platinum and silver.

As mentioned above, the electrophotographic electrode ink composition may include a charge adjuvant and a liquid carrier. A charge director may also be present.

These components are described in further detail below.

### Thermoplastic Polymer

As described above, the electrophotographic active ink composition and the electrophotographic electrode ink composition may each include a thermoplastic polymer comprising a copolymer of an olefin and acrylic acid and/or methacrylic acid. In some examples, the thermoplastic polymer comprises a copolymer of an olefin and acrylic acid. In some examples, the thermoplastic polymer comprises a copolymer of ethylene and acrylic acid. The acrylic acid content of the copolymer may be 5 to 30 weight %, for example, 10 to 25 weight % or 12 to 20 weight % of the total weight of the copolymer. The acrylic acid content of the copolymer may be 15 to 18 weight % of the total weight of the copolymer. An example of a suitable copolymer is an ethylene acrylic acid copolymer comprising 15 weight % of units derived from acrylic acid sold under the trademark Honeywell® AC-5120.

The polymer may have a melting point of less than 110 degrees C. or less than 100 degrees C. In one example, the polymer may have a melting point of 50 to up to 110 degrees C., for example, 60 to 100 degrees C. Where a polymer mixture is present, the polymer mixture may have a melting point of less than 110 degrees C. or less than 100 degrees C. In one example, the polymer mixture may have a melting point of 50 to up to 110 degrees C., for example, 60 to 100 degrees C.

In one example, the polymer is a polymer of an olefin (e.g. ethylene) and an acrylic acid (e.g. acrylic acid or methacrylic acid) or acrylate (e.g. acrylate or methacrylate) having a melting point of less than 110 degrees C. or less than 100 degrees C. In one example, the polymer is a polymer of an olefin (e.g. ethylene) and an acrylic acid (e.g. acrylic acid or methacrylic acid) or acrylate (e.g. acrylate or methacrylate) having a melting point of 50 to up to 110 degrees C., for example, 60 to 100 degrees C. or 70 to 95 degrees C. Where the electrophotographic composition comprises a mixture of two or more polymers, at least 50 weight %, at least 60 weight %, at least 70 weight %, at least 80 weight % or at least 90 weight % of the polymer mixture may be formed of polymer(s) having melting points of less than 110 degrees C. or less than 100 degrees C. In one example, at least 50 weight % at least 60 weight %, at least 70 weight %, at least 80 weight % or at least 90 weight % of the polymer mixture may be formed of polymer(s) having melting points of 50 to up to 110 degrees C., for example, 60 to 100 degrees C.

In one example, polymer is a polymer of an olefin (e.g. ethylene) and at least one monomer selected from an acrylic or acrylate monomer, for instance, methacrylic acid, acrylic acid, acrylate and methacrylate. The polymer may comprise at least 80 weight % olefin (e.g. ethylene), for example, 80 to 90 weight % olefin (e.g. ethylene). The polymer may include 10 to 20 weight % of an acrylic or acrylate monomer, for example, at least one of methacrylic acid, acrylic acid, acrylate and methacrylate.

In one example, the polymer is a polymer of an olefin (e.g. ethylene) and methacrylic acid. The polymer may include 80 to 90 weight % ethylene and 10 to 20 weight % methacrylic acid. The polymer may include 85 weight % ethylene and the remainder methacrylic acid. In one example, the polymer is or comprises a polymer sold under the trademark Nucrel®925.

In one example, the polymer is a polymer of an olefin (e.g. ethylene) and acrylic acid. The polymer may include 80 to 90 weight % ethylene and 10 to 20 weight % acrylic acid. The polymer includes 82 weight % ethylene and the remainder acrylic acid. In one example, the polymer is or comprises a polymer sold under the trademark Nucrel® 2806.

In one example, the polymer resin may include more than one polymer. In an example, the polymer resin may include 2 or 3 polymers. In one example, the polymer comprises a polymer of an olefin (e.g. ethylene) and acrylic acid and a polymer of an olefin (e.g. ethylene) and methacrylic acid. For example, the polymer resin may include a first resin formed of 80 to 90 weight % ethylene and 10 to 20 weight % methacrylic acid, and a second resin formed of 80 to 90 weight % ethylene and 10 to 20 weight % acrylic acid. Where the polymer resin contains a first resin and a second resin, the amount of the first resin may be 60 to 80 weight %, for example, 65 to 75 weight % of the polymer resin mixture. The amount of second resin may be 15 to 25 weight %, for example, 17 to 22 weight % of the polymer resin mixture. The weight ratio the first resin to the second resin may be 2:1 to 5:1, for example, 3:1 to 4:

In one example, the polymer resin includes a first resin formed of 85 weight % ethylene and the remainder methacrylic acid, and a second resin formed of 82 weight % ethylene and the remainder acrylic acid. In one example, the polymer resin includes a mixture of a polymer sold under the trademark Nucrel® 6925 and a polymer sold under the trademark Nucrel®2806.

In addition to a copolymer of ethylene and at least one monomer selected from an acrylic or acrylate monomer e.g. as described above, the polymer may also include a terpolymer. The terpolymer may be a terpolymer of a) an olefin (e.g. ethylene), b) an acrylic acid (e.g. acrylic acid or methacrylic acid) or an acrylate (e.g. acrylate or methacrylate) and c) a polar monomer. The olefin (e.g. ethylene) may form 60 to 78 weight % of the terpolymer, for example, 65 to 70 weight % of the terpolymer. The acrylic acid (e.g. acrylic acid or methacrylic acid) or acrylate (e.g. acrylate or methyl acrylate) may form 20 to 35 weight % of the terpolymer, for example, 22 to 30 weight % of the terpolymer. The polar monomer may form the remainder of the terpolymer. Examples of suitable polar monomers include monomers containing amine, amide, ester, ether and/or anhydride functional groups. In one example, the polar monomer contains amide, amine, groups, anhydride groups or both ester and ether groups. In an example, the polar monomer is selected from maleic anhydride or glycidyl methacrylate.

In one example, the terpolymer is a terpolymer of ethylene, methacrylic acid and glycidyl methacrylate. The amount of ethylene may be 60 to 78 weight % of the polymer, for example, 65 to 70 weight % of the terpolymer. The amount of methacrylic acid may range from 20 to 35 weight % of the terpolymer, for example, 22 to 30 weight % of the terpolymer. The remainder of the polymer may be derived from glycidyl methacrylate. In one example, the terpolymer comprises 68 weight % ethylene, 24 weight % methacrylic acid and 8 weight % glycidyl methacrylate. The terpolymer may be one sold under the trademark Lotader® AX8900. The terpolymer may be used in combination with a copolymer of ethylene and methacrylic acid or acrylic acid. For example, such terpolymers (for instance one sold under the trademark Lotader® AX8900) may be employed in combination with polymers sold under the trademark Nucrel®925.

In one example, the terpolymer is a terpolymer of ethylene, ethyl acrylate and maleic anhydride. The amount of ethylene may be 60 to 80 weight % of the terpolymer, for example, 65 to 70 weight % of the terpolymer. The amount of ethyl acrylate may range from 19 to 35 weight % of the terpolymer, for example, 20 to 30 weight % of the terpolymer. The remainder of the terpolymer may be derived from maleic anhydride. In one example, the amount of maleic anhydride may be 0.1 to 5 weight %, for example, 1 to 3 weight %. In one example, the terpolymer comprises 70 weight % ethylene, 29 weight % ethyl acrylate and 1.3 weight % maleic anhydride. The terpolymer may be used in combination with a copolymer of ethylene and methacrylic acid or acrylic acid. The terpolymer may be sold under the trademark Lotader® 4700. Alternatively, the polymer B may be one or more polymers sold under the trademark Lotader® 5500, Lotader® 4503 and Lotader® 4720. Such terpolymers (for instance one sold under the trademark Lotader® 4700) may be employed in combination with polymers sold under the trademark Nucrel®925.

Where a terpolymer is employed, the terpolymer may form 1 to 50 weight % of the polymer resin. In some examples, the terpolymer forms 1 to 20 weight %, for instance 5 to 15 weight % of the polymer resin. Where a copolymer of an olefin (e.g.) and an acrylic or acrylate (e.g. methacrylic acid, acrylic acid, methacrylate or acrylate) is employed, the copolymer may form 50 to 100 weight %, for example, 70 to 99 weight %, for instance, 80 or 85 to 95 weight % of the polymer resin.

The polymer resin may have a melting point of less than 110 degrees C., for example, less than 100 degrees C.

The polymer resin may have (or may contain a polymer having) an acidity of 50 mg KOH/g or more, in some examples an acidity of 60 mg KOH/g or more, in some examples an acidity of 70 mg KOH/g or more, in some examples an acidity of 80 mg KOH/g or more, in some examples an acidity of 90 mg KOH/g or more, in some examples an acidity of 100 mg KOH/g or more, in some examples an acidity of 105 mg KOH/g or more, in some examples 110 mg KOH/g or more, in some examples 115 mg KOH/g or more. The polymer may have an acidity of 200 mg KOH/g or less, in some examples 190 mg or less, in some examples 180 mg or less, in some examples 130 mg KOH/g or less, in some examples 120 mg KOH/g or less. Acidity of a polymer, as measured in mg KOH/g can be measured using standard procedures known in the art, for example using the procedure described in ASTM D1386.

The resin may comprise a polymer that has a melt flow rate of less than about 70 g/10 minutes, in some examples about 60 g/10 minutes or less, in some examples about 50 g/10 minutes or less, in some examples about 40 g/10 minutes or less, in some examples 30 g/10 minutes or less, in some examples 20 g/10 minutes or less, in some examples 10 g/10 minutes or less. In some examples, all polymers each individually have a melt flow rate of less than 90 g/10 minutes, 80 g/10 minutes or less, in some examples 80 g/10 minutes or less, in some examples 70 g/10 minutes or less, in some examples 70 g/10 minutes or less, in some examples 60 g/10 minutes or less.

The resin may comprise a polymer having a melt flow rate of about 10 g/10 minutes to about 120 g/10 minutes, in some examples about 10 g/10 minutes to about 70 g/10 minutes, in some examples about 10 g/10 minutes to 40 g/10 minutes, in some examples 20 g/10 minutes to 30 g/10 minutes. The polymer having acidic side groups can have a melt flow rate of, in some examples, about 50 g/10 minutes to about 120 g/10 minutes, in some examples 60 g/10 minutes to about 100 g/10 minutes. The melt flow rate can be measured using standard procedures known in the art, for example as described in ASTM D1238.

Where a terpolymer is present, this may have a melt index of 1 to 20 g/10 min, for instance, 1 to 9 g/10 or 10 g/10 min. In another example, the terpolymer has a melt index of 3 to 8 g/10 min, for instance, 4 to 7 g/10 min.

Where a copolymer of an olefin (e.g.) and an acrylic or acrylate (e.g. methacrylic acid, acrylic acid, methacrylate or acrylate) is employed, the copolymer may have a melt index of 20 to 200 g/10 min, for example, 25 to 70 g/10 min. In one example, the copolymer has a melt index of 25 to 35 g/10 min. This copolymer may be used in combination with another copolymer of an olefin (e.g.) and an acrylic or acrylate (e.g. methacrylic acid, acrylic acid, methacrylate or acrylate) having a melt index of 50 to 70 g/10 min.

The acidic side groups may be in free acid form or may be in the form of an anion and associated with one or more counterions, typically metal counterions, e.g. a metal selected from the alkali metals, such as lithium, sodium and potassium, alkali earth metals, such as magnesium or calcium, and transition metals, such as zinc. The polymer having acidic sides groups can be selected from resins such as co-polymers of ethylene and an ethylenically unsaturated acid of either acrylic acid or methacrylic acid; and ionomers thereof, such as methacrylic acid and ethylene-acrylic or methacrylic acid co-polymers which are at least partially neutralized with metal ions (e.g. Zn, Na, Li) such as ionomers sold under the trademark SURLYN®. The polymer comprising acidic side groups can be a co-polymer of ethylene and an ethylenically unsaturated acid of either acrylic or methacrylic acid, where the ethylenically unsaturated acid of either acrylic or methacrylic acid constitute from 5 wt % to about 25 wt % of the co-polymer, in some examples from 10 wt % to about 20 wt % of the co-polymer.

The resin may comprise two different polymers having acidic side groups. The two polymers having acidic side groups may have different acidities, which may fall within the ranges mentioned above. The resin may comprise a first polymer having acidic side groups that has an acidity of from 10 mg KOH/g to 110 mg KOH/g, in some examples 20 mg KOH/g to 110 mg KOH/g, in some examples 30 mg KOH/g to 110 mg KOH/g, in some examples 50 mg KOH/g to 110 mg KOH/g, and a second polymer having acidic side groups that has an acidity of 110 mg KOH/g to 130 mg KOH/g.

The resin may comprise two different polymers having acidic side groups: a first polymer having acidic side groups that has a melt flow rate of about 10 g/10 minutes to about 50 g/10 minutes and an acidity of from 10 mg KOH/g to 110 mg KOH/g, in some examples 20 mg KOH/g to 110 mg KOH/g, in some examples 30 mg KOH/g to 110 mg KOH/g, in some examples 50 mg KOH/g to 110 mg KOH/g, and a second polymer having acidic side groups that has a melt flow rate of about 50 g/10 minutes to about 120 g/10 minutes and an acidity of 110 mg KOH/g to 130 mg KOH/g. The first and second polymers may be absent of ester groups.

The ratio of the first polymer having acidic side groups to the second polymer having acidic side groups can be from about 10:1 to about 2:1. The ratio can be from about 6:1 to about 3:1, in some examples about 4:1.

The resin may comprise a polymer having a melt viscosity of 15000 poise or less, in some examples a melt viscosity of 10000 poise or less, in some examples 1000 poise or less, in some examples 100 poise or less, in some examples 50 poise or less, in some examples 10 poise or less; said polymer may be a polymer having acidic side groups as described in this disclosure. The resin may comprise a first polymer having a melt viscosity of 15000 poise or more, in some examples 20000 poise or more, in some examples 50000 poise or more, in some examples 70000 poise or more; and in some examples, the resin may comprise a second polymer having a melt viscosity less than the first polymer, in some examples a melt viscosity of 15000 poise or less, in some examples a melt viscosity of 10000 poise or less, in some examples 1000 poise or less, in some examples 100 poise or less, in some examples 50 poise or less, in some examples 10 poise or less. The resin may comprise a first polymer having a melt viscosity of more than 60000 poise, in some examples from 60000 poise to 100000 poise, in some examples from 65000 poise to 85000 poise; a second polymer having a melt viscosity of from 15000 poise to 40000 poise, in some examples 20000 poise to 30000 poise, and a third polymer having a melt viscosity of 15000 poise or less, in some examples a melt viscosity of 10000 poise or less, in some examples 1000 poise or less, in some examples 100 poise or less, in some examples 50 poise or less, in some examples 10 poise or less. The melt viscosity can be measured using a rheometer, e.g. a commercially available AR-2000 Rheometer from Thermal Analysis Instruments, using the geometry of: 25 mm steel plate-standard steel parallel plate, and finding the plate over plate rheometry isotherm at 120° C., 0.01 hz shear rate.

If the resin in the electrophotographic composition comprises a single type of polymer, the polymer (excluding any other components of the electrostatic composition) may have a melt viscosity of 6000 poise or more, in some examples a melt viscosity of 8000 poise or more, in some examples a melt viscosity of 10000 poise or more, in some examples a melt viscosity of 12000 poise or more. If the resin comprises a plurality of polymers all the polymers of the resin may together form a mixture (excluding any other components of the electrostatic composition) that has a melt viscosity of 6000 poise or more, in some examples a melt viscosity of 8000 poise or more, in some examples a melt viscosity of 10000 poise or more, in some examples a melt viscosity of 12000 poise or more. Melt viscosity can be measured using standard techniques. The melt viscosity can be measured using a rheometer, e.g. a commercially available AR-2000 Rheometer from Thermal Analysis Instruments, using the geometry of: 25 mm steel plate-standard steel parallel plate, and finding the plate over plate rheometry isotherm at 120° C., 0.01 Hz shear rate.

The resin can constitute about 5 to up to 100 weight %, in some examples about 50 to 99%, by weight of the solids of the liquid electrophotographic composition. The resin can constitute about 60 to 95%, in some examples about 70 to 95%, by weight of the solids of the liquid electrophotographic composition.

For the avoidance of doubt, the polymer or polymer mixture used in the electrophotographic electrode ink composition may be the same or different to the polymer or polymer mixture used in the electrophotographic active ink composition.

### Charge Adjuvant

As mentioned above, the electrophotographic active composition includes a charge adjuvant. The electrophotographic electrode ink composition can also include a charge adjuvant. A charge adjuvant may be present with or without a charge director, and may be different to the charge director, and act to increase and/or stabilise the charge on particles, e.g. resin-containing particles, of an electrostatic composition.

The charge adjuvant can include, but is not limited to, barium petronate, calcium petronate, Co salts of naphthenic acid, Ca salts of naphthenic acid, Cu salts of naphthenic acid, Mn salts of naphthenic acid, Ni salts of naphthenic acid, Zn salts of naphthenic acid, Fe salts of naphthenic acid, Ba salts of stearic acid, Co salts of stearic acid, Pb salts of stearic acid, Zn salts of stearic acid, Ai salts of stearic acid, Cu salts of stearic acid, Fe salts of stearic acid, metal carboxylates (e.g. Al tristearate, Al octanoate, Li heptanoate, Fe stearate, Fe distearate, Ba stearate, Cr stearate, Mg octanoate, Ca stearate, Fe naphthenate, Zn naphthenate, Mn heptanoate, Zn heptanoate, Ba octanoate, Al octanoate, Co octanoate, Mn octanoate, and Zn octanoate), Co lineolates, Mn lineolates, Pb lineolates, Zn lineolates, Ca oleates, Co oleates, Zn palmirate, Ca resinates, Co resinates, Mn resinates, Pb resinates, Zn resinates, AB dibock co-polymers of 2-ethylhexyl methacrylate-co-methacrylic acid calcium, and ammonium salts, co-polymers of an alkyl acrylamidoglycolate alkyl ether (e.g. methyl acrylamidogycolate methyl ether-co-vinyl acetate), and hydroxy bis(3,5-di-tert-butyl salicylic) aluminate monohydrate. In some examples, the charge adjuvant is aluminium di and/or tristearate and/or aluminium di and/or tripalmitate.

The charge adjuvant can constitute about 0.1 to 5% by weight of the solids of the liquid electrophotographic composition. The charge adjuvant can constitute about 0.5 to 4% by weight of the solids of the liquid electrophotographic composition. The charge adjuvant can constitute about 1 to 3% by weight of the solids of the liquid electrophotographic active or electrode ink composition.

### Charge Director

As an optional component, a charge director may be added to the electrophotographic active ink and/or electrode ink composition. In some examples, the charge director comprises nanoparticles of a simple salt and a salt of the general formula MA,, wherein M is a barium, n is 2, and A is an ion of the general formula [R₁—O—C(O)CH₂CH(SO₃⁻)C(O)—O—R₂], where each of R₁ and R₂ is an alkyl group e.g. as discussed above.

The sulfosuccinate salt of the general formula MA is an example of a micelle forming salt. The charge director may be substantially free or free of an acid of the general formula HA, where A is as described above. The charge director may comprise micelles of said sulfosuccinate salt enclosing at least some of the nanoparticles. The charge director may comprise at least some nanoparticles having a size of 10 nm or less, in some examples 2 nm or more (e.g. 4-6 nm).

The simple salt may comprise a cation selected from Mg, Ca, Ba, NH₄, tert-butyl ammonium, Li⁺, and Al⁺³, or from any sub-group thereof. In one example, the simple salt is an inorganic salt, for instance, a barium salt. The simple salt may comprise an anion selected from SO₄²⁻, PO³⁻, NO₃⁻, HPO₄²⁻, CO₃²⁻, acetate, trifluoroacetate (TFA), Cl⁻, Bf, F⁻, ClO₄⁻, and TiO₃⁴⁻, or from any sub-group thereof. In some examples, the simple salt comprises a hydrogen phosphate anion.

The simple salt may be selected from CaCO₃, Ba₂TiO₃, A₂(SO₄)₃, A(NO₃)₃, Ca₃(PO₄)₂, BaSO₄, BaHPO₄, Ba₂(PO₄)₃, CaSO₄, (NH₄)₂CO₃, (NH₄)₂SO₄, NH₄OAc, Tert-butyl ammonium bromide, NH₄NO₃, LITFA, Al₂(SO₄)₃, LiCIO₄ and LiBF₄, or any sub-group thereof. In one example, the simple salt may be BaHPO₄.

In the formula [R₁—O—C(O)CH₂CH(SO₃⁻)C(O)—O—R₂], in some examples, each of R₁ and R₂ is an aliphatic alkyl group. In some examples, each of R₁ and R₂ independently is a C₆₋₂₅ alkyl. In some examples, said aliphatic alkyl group is linear. In some examples, said aliphatic alkyl group is branched. In some examples, said aliphatic alkyl group includes a linear chain of more than 6 carbon atoms. In some examples, R₁ and R₂ are the same. In some examples, at least one of R₁ and R₂ is C₁₃H₂₇.

In the electrophotographic active ink or electrode ink composition, the charge director can constitute about 0.001% to 20%, in some examples 0.01 to 20% by weight, in some examples 0.01 to 10% by weight, in some examples 0.01 to 1% by weight of the solids of the composition. The charge director can constitute about 0.001 to 0.15% by weight of the solids of the composition, in some examples 0.001 to 0.15%, in some examples 0.001 to 0.02% by weight of the solids of the composition. In some examples, the charge director imparts a negative charge on the electrostatic composition. The particle conductivity may range from 50 to 500 pmho/cm, in some examples from 200-350 pmho/cm.

### Carrier Liquid

The electrophotographic active ink and/or electrode ink composition may be printed in liquid form. Generally, the carrier liquid for the liquid composition can act as a dispersing medium for the other components in the electrostatic composition. For example, the carrier liquid can comprise or be a hydrocarbon, silicone oil, vegetable oil, etc. The carrier liquid can include, but is not limited to, an insulating, non-polar, non-aqueous liquid that can be used as a medium for toner particles. The carrier liquid can include compounds that have a resistivity in excess of about 10⁹ ohm-cm. The carrier liquid may have a dielectric constant below about 5, in some examples below about 3. The carrier liquid can include, but is not limited to, hydrocarbons. The hydrocarbon can include, but is not limited to, an aliphatic hydrocarbon, an isomerized aliphatic hydrocarbon, branched chain aliphatic hydrocarbons, aromatic hydrocarbons, and combinations thereof. Examples of the carrier liquids include, but are not limited to, aliphatic hydrocarbons, isoparaffinic compounds, paraffinic compounds, dearomatized hydrocarbon compounds, and the like. In some examples, the carrier liquid is an isoparaffinic liquid. In particular, the carrier liquids can include, but are not limited to liquids sold under the trademarks, Isopar®-G™, Isopar-H™, Isopar-L™, Isopar-M™, Isopar-K™, Isopar-V™, Norpar 12™, Norpar 13™, Norpar 15™, Exxol D40™, Exxol D80™, Exxol D100™, Exxol D130™, and Exxol D140™ (each sold by EXXON CORPORATION); Teclen N-16™, Teclen N-20™, Teclen N-22™, Nisseki Naphthesol L™, Nisseki Naphthesol M™, Nisseki Naphthesol H™, #0 Solvent L™, #0 Solvent M™, #0 Solvent H™, Nisseki Isosol 300™, Nisseki Isosol 400™, AF-4™, AF-5™, AF-6™ and AF-7™ (each sold by NIPPON OIL CORPORATION); IP Solvent 1620™ and IP Solvent 2028™ (each sold by IDEMITSU PETROCHEMICAL CO., LTD.); Amsco OMS™ and Amsco 460 ™ (each sold by AMERICAN MINERAL SPIRITS CORP.); and Electron, Positron, New II, Purogen HF (100% synthetic terpenes) (sold by ECOLINK™).

Before printing, the carrier liquid can constitute about 20% to 99.5% by weight of the electrostatic composition, in some examples 50% to 99.5% by weight of the electrostatic composition. Before printing, the carrier liquid may constitute about 40 to 90% by weight of the electrostatic composition. Before printing, the carrier liquid may constitute about 60% to 80% by weight of the electrostatic composition. Before printing, the carrier liquid may constitute about 90% to 99.5% by weight of the electrostatic composition, in some examples 95% to 99% by weight of the electrostatic composition.

The composition when printed on the print substrate, may be substantially free from carrier liquid. In an electrostatic printing process and/or afterwards, the carrier liquid may be removed, e.g. by an electrophoresis processes during printing and/or evaporation, such that substantially just solids are transferred to the print substrate. Substantially free from carrier liquid may indicate that the ink printed on the print substrate contains less than 5 wt % carrier liquid, in some examples, less than 2 wt % carrier liquid, in some examples less than 1 wt % carrier liquid, in some examples less than 0.5 wt % carrier liquid. In some examples, the ink printed on the print substrate is free from carrier liquid.

### Cell Assembly

As mentioned above, an aspect of the disclosure relates to a method of assembling a photovoltaic cell. The method comprises electrophotographically printing an active photovoltaic layer over a transparent anode; and electrophotographically printing a cathode over the active photovoltaic layer. For the avoidance of doubt, the active photovoltaic layer may be in direct contact with the transparent anode. Alternatively, at least one intervening layer may be present, for example, a hole transport layer. The cathode may also be in direct contact with the active photovoltaic layer. Alternatively, at least one intervening layer may be present, for example, an electron transport layer.

Any suitable transparent anode may be employed. The anode may comprise a coated substrate that is optically transparent and electrically conducting. In one example, indium tin oxide coated substrate may be employed. The substrate may be a glass or transparent plastic substrate. Suitable plastic substrates include PET and polypropylene (e.g. oriented polypropylene BOPP). Other examples of suitable transparent anodes include fluorine tin oxide coated substrates (e.g. glass), gold coated substrates (e.g. glass or mica); silicon wafers; and single crystal substrates formed, for example, of aluminium oxide, gallium antimonide, gallium phosphide, gallium arsenide, lanthanum aluminium oxide, magnesium aluminate, magnesium oxide, silicon dioxide, strontium lanthanum aluminate, strontium titanate and titanium (IV) oxide.

As mentioned above, the active photovoltaic layer and cathode are electrophotographically printed. In electrophotographic printing, an image is first created on a photoconductive surface or photo imaging plate (PIP). The image that is formed on the photoconductive surface is a latent electrostatic image having image and background areas with different potentials. When an electrophotographic composition containing charged toner particles is brought into contact with the selectively charged photoconductive surface, the charged toner particles adhere to the image areas of the latent image while the background areas remain clean. The image is then transferred to a print substrate either directly or by first being transferred to an intermediate transfer member (e.g. a soft swelling blanket) and then to the print substrate. The intermediate transfer member, if present, may be a rotating flexible member, which may be heated, e.g. to a temperature of from 80 to 105 degrees C.

In the case of the liquid electrophotographic active ink compositions of the present disclosure, the toner particles include active photovoltaic material. The active photovoltaic material may therefore be printed onto the substrate to form the active photovoltaic layer. The active photovoltaic layer may comprise an admixture, for example an intimate admixture of the electron donor material and electron acceptor material.

The homology of the active photovoltaic layer may be controlled at least to some extent by controlling the way in which the electrophotographic active ink composition is prepared. For example, to ensure that the electron donor material and electron acceptor material is adequately mixed, particles of the electron donor material and electron acceptor material may be ground together. The particles may be ground in the presence of the thermoplastic resin particles to form toner ink particles that can be electrophotographically printed in an effective manner.

In some examples, an intimate mixture of the electron donor material and electron acceptor material may first be formed prior to addition of the resin. The mixture may be formed by grinding. Alternatively, the mixture may be formed by dissolving the electron donor material and electron acceptor material in a suitable solvent, then evaporating the solvent to produce the intimate mixture of the particles. This mixture may then be ground with the thermoplastic resin.

Because the active photovoltaic material is printed together with the thermoplastic resin, the resulting active photovoltaic layer includes the thermoplastic resin. Thus, in another aspect, the disclosure provides electrophotographically printed photovoltaic cell comprising a transparent anode, an electrophotographically printed active photovoltaic layer overlying the transparent anode, and an electrophotographically printed cathode overlying the electrophotographically printed active photovoltaic layer, wherein the electrophotographically printed active photovoltaic layer comprises a thermoplastic resin comprising a copolymer of an olefin and acrylic acid and/or methacrylic acid, and a mixture of electron donor material and electron acceptor material.

The printed photovoltaic cell may be suitable for converting, for example, visible light to electricity. Alternatively, the photovoltaic cell may be suitable for converting, for example, infrared or UV light to electricity. The photovoltaic cell may be suitable for converting wavelengths of 300 to 10000 nm, for example, 300 to 1000 nm. In some examples, the cell may be suitable for converting wavelengths of 380 to 750 nm.

The printed photovoltaic cell may be attached to any suitable substrate, for example, a print substrate. Examples of suitable print substrates include posters, banners or packaging material. The substrate may be a print substrate that is intended to be electrophotographically printed with an image. Such a print substrate may be a polymeric material, paper or a metallic material.

The printed photovoltaic cell may be used in combination with an electrochemical cell, for example, a battery. The cell or battery may be electrophotographicaly printed on a print substrate. The cell or battery may be used to store electrical energy generated by light falling on the photovoltaic cell.

The electrical energy generated by the photovoltaic cell may be used to power e.g. lights or circuitry on the print substrate, for example, to provide a visual or aural effect. In some examples, electrical energy generated by the photovoltaic cell may first be stored in a cell or battery. The stored energy may subsequently be used to power e.g. lights or circuitry on the print substrate, for example, to provide a visual or aural effect.

In some examples, a series of photovoltaic cells may be provided.

Various examples will now be described.

### EXAMPLES

### Materials:

A-C 5120 (supplied by Honeywell®) as thermoplastic resin component
Fullerene
Zinc Phthalocyanine
Multi-walled carbon nanotubes—(MWCNT) as electroconductive carbon material
Aluminium stearate

### Paste Preparation:

In this method, resin A-C 5120 at 50-57% NVS was inserted in Ross tool and was melted under 50 rpm mixing at 130° C. during 60 minutes. After 60 minutes the mixing velocity was raised to 70 rpm to enhance melting and to produce a paste. This phase was continued for 90 minutes. Then, the paste was cooled to 25° C. under constant mixing at 50 rpm. The cooling took place over 3-4 hours.

### Ink Preparation

### Liquid Electrophotographic Electrode (Cathode) Ink Composition:

The paste produced above (˜55% non-volatile solids (NVS) in iso-paraffin (Isopar®-L (Sol-L)), carbo nanotubes (MWCNT) and charging adjuvant (aluminium stearate) were loaded into an Attritor containing metal grinding balls in the amounts shown in Table 1 below. The grinding process was performed at ˜43° C. (mixing speed of 250 rpm) for 5 hrs). After reaching the particle size (below 8 micron), the ink was diluted with iso-paraffin (Isopar®-L, Sol-L) and mixed for 15 minutes before being discharged to a receiving container. The % NVS of the obtained ink is in the range of 3-10% NVS.

TABLE 1

| MATERIALS: | Wt(%) |
|---|---|
| Paste | 68.00 |
| CNT | 30.00 |
| aluminium stearate | 2.00 |
| TOTAL NVS % | 18.00 |

### Active Layer

The paste produced above (˜55% non-volatile solids (NVS) in iso-paraffin (Isopar®-L (Sol-L)), zinc phthalocyanine, fullerene and charging adjuvant were loaded into an Attritor containing metal grinding balls in the amounts shown in Table 2 below. The grinding process was performed at ˜43° C. (mixing speed of 250 rpm) for 5 hrs). After reaching the particle size (below 8 micron), the ink was diluted with iso-paraffin (Isopar®-L, Sol-L) and mixed for 15 minutes before being discharged to a receiving container. The % NVS of the obtained ink is in the range of 3-10% NVS.

TABLE 2

| MATERIALS | Wt(%) |
|---|---|
| Paste | 68.00 |
| Zinc Phthalocyanine | 15.00 |
| Fullerene | 15.00 |
| aluminium stearate | 2.00 |
| TOTAL % NVS | 18.00 |

### Anode:

ITO film on transparent plastic substrate was used as the anode. The anode was acquired from TDK®.

### Working Dispersion Preparation:

Before the inks above were printed, they were diluted to form working dispersions. To do this, 3.5 KG of ink 2% NVS were prepared by diluting the inks with iso-paraffin (Isopar®-L, Sol-L). A charge director (NCD) was added till low field of 70 pmho was reached and the dispersion was mixed in a shaker (200 rpm) for 24 h to reach sufficient charging, homogenization and stabilisation.

### Cell Assembly and Testing—1

A working dispersion formed using the liquid electrophotographic active composition was electrophotograpically printed onto the anode to form an active photovoltaic layer over the anode. A working dispersion formed using the liquid electrophotographic electrode ink composition was electrophotographically printed onto the active photovoltaic layer to form a cathode over the active photovoltaic layer.

The resulting photovoltaic cell was irradiated using a lamp, and the potential difference across the cell was measured to be 20 mV (by single cell).

1. An electrophotographic active ink composition comprising:
a thermoplastic polymer comprising a copolymer of an olefin and acrylic acid and/or methacrylic acid;
active photovoltaic material comprising electron donor material and electron acceptor material;
a charge adjuvant, and
a liquid carrier.

2. A composition as claimed in claim 1, wherein the electron donor material is a conjugated organic material.

3. A composition as claimed in claim 2, wherein the conjugated organic material is selected from phthalocyanines, poythiophenes, poly(phenylene vinylenes) (PPV's), polyfluorenes, poly(p-phenylene), quinolines and derivatives thereof.

4. A composition as claimed in claim 3, wherein the conjugated organic material is selected from zinc phthaocyanine, copper phthalocyanine and poly(3-hexylthiophene-2,5-diyl).

5. A composition as claimed in claim 1, wherein the electron acceptor material is a fullerene, perylene or derivatives thereof.

6. A composition as claimed in claim 1, which further comprises a charge director.

7. A composition as claimed in claim 1, wherein the weight ratio of electron donor material to electron acceptor material is 1:5 to 5:1.

8. A composition as claimed in claim 1, wherein the ratio of the total weight of active photovoltaic material to the total weight of thermoplastic polymer is 1:5 to 5:1.

9. A composition as claimed in claim 1, wherein the total weight of active photovoltaic material in the composition is 15 to 85 weight % based on the total weight of solids of the composition.

10. A material set comprising an electrophotographic active ink composition as claimed in claim 1, and an electrophotographic electrode ink composition comprising
a thermoplastic polymer comprising a copolymer of an olefin and acrylic acid and/or methacrylic acid;
an electrically conductive material comprising carbon or metal;
a charge adjuvant, and
a liquid carrier.

11. A material set as claimed in claim 10, wherein the electrically conductive material comprises carbon nanotubes, carbon black, graphene and/or graphite.

12. A material set as claimed in claim 11, wherein the amount of electrically conductive material in the composition is 1 to 70 weight % based on the total weight of solids of the composition.

13. A method of assembling a photovoltaic cell, said method comprising
electrophotographically printing an active photovoltaic layer over a transparent anode using an electrophotographic active ink composition comprising a thermoplastic polymer comprising a copolymer of an olefin and acrylic acid and/or methacrylic acid; active photovoltaic material comprising electron donor material and electron acceptor material; a charge adjuvant, and liquid carrier; and
electrophotographically printing a cathode over the active photovoltaic layer using a thermoplastic polymer comprising a copolymer of an olefin and acrylic acid and/or methacrylic acid; an electrically conductive material comprising carbon or metal; a charge adjuvant, and a liquid carrier.

14. A method as claimed in claim 13, wherein the active photovoltaic layer comprises an intimate mixture of particles of the electron donor material and electron acceptor material.

15. An electrophotographically printed photovoltaic cell comprising a transparent anode, an electrophotographically printed active photovoltaic layer overlying the transparent anode, and an electrophotographically printed cathode overlying the electrophotographically printed active photovoltaic layer, wherein the electrophotographically printed active photovoltaic layer comprises a thermoplastic resin comprising a copolymer of an olefin and acrylic acid and/or methacrylic acid, and a mixture of electron donor material and electron acceptor material.
